(19) United States
(12) Patent Application Publication
(10) Pub. No.: US 2025/0183867 A1
(43) Pub. Date: Jun. 5, 2025

(54) BAND-PASS FILTER

(71) Applicant: INDUSTRIAL TECHNOLOGY RESEARCH INSTITUTE, Hsinchu (TW)

(72) Inventor: Jiun-Jang YU, Hsinchu City (TW)

(73) Assignee: INDUSTRIAL TECHNOLOGY RESEARCH INSTITUTE, Hsinchu (TW)

(21) Appl. No.: 18/962,935

(22) Filed: Nov. 27, 2024

(30) Foreign Application Priority Data
Dec. 4, 2023 (TW) 112147088
Nov. 20, 2024 (TW) 113144758

(51) Int. Cl. H03H 7/01

(52) U.S. Cl. CPC H03H 7/0115

(57) ABSTRACT

A band-pass filter includes a body, two input-output pillars, resonance pillars and a conductive cage. The input-output pillars are located on two opposite sides of the body in a direction. Each of the resonance pillars is disposed in the body and has a first end and a second end. The input-output resonance pillars of the resonance pillars are adjacent to the input-output pillars and electrically connected to the input-output pillars. The intermediate resonance of the resonance pillar is located between the input-output resonance pillars in the direction. The conductive cage surrounds the resonance pillars and includes a bottom layer, a top layer and side connectors. The first ends are connected to the bottom layer. The second ends are spaced apart from the top layer. A minimum distance between each of the resonance pillars and the side connectors is less than a minimum distance between the resonance pillars.

This non-provisional application claims priority under 35 U.S.C. § 119 (a) on patent U.S. application Ser. No. 11/214,7088 filed in Taiwan, R.O.C. on Dec. 4, 2023 and No. 113144758 filed in Taiwan, R.O.C. on Nov. 20, 2024, the entire contents of which are hereby incorporated by reference.

### TECHNICAL FIELD

The disclosure relates to a filter, and in particular to a band-pass filter.

### BACKGROUND

Among various passive components of electronic components, filters may filter out signals with certain frequencies. Thereby, noise may be filtered out. Furthermore, a band-pass filter may allow signals with a specific frequency and a specific bandwidth to pass through.

Currently, electronic devices generally have a requirement of miniaturization. Therefore, the band-pass filter also have the requirement of miniaturization.

### SUMMARY

One embodiment of the disclosure provides a band-pass filter including a body, two input-output pillars, a plurality of resonance pillars and a conductive cage. The input-output pillars are located on two opposite sides of the body in a direction. The resonance pillars are disposed in the body. Each of the resonance pillars has a first end and a second end. The resonance pillars include two input-output resonance pillars and at least one intermediate resonance pillar. The input-output resonance pillars are respectively disposed adjacent to and electrically connected to the input-output pillars. The intermediate resonance pillar is located between the two input-output resonance pillars in the above direction. The conductive cage is disposed surrounding the resonance pillars. The conductive cage includes a bottom layer, a top layer and a plurality of side connectors. The side connectors are disposed connecting the bottom layer and the top layer. The first ends of the resonance pillars are connected to the bottom layer. The second ends of the resonance pillars are disposed to be spaced apart from the top layer. A minimum distance between each of the resonance pillars and one of the side connectors is less than a minimum distance between two of the resonance pillars. The band-pass filter further includes a plurality of capacitive conductors disposed in the body, spaced apart from the top layer and respectively connected to the second ends of the resonance pillars.

According to the band-pass filter of one embodiment of the disclosure, the first ends of the resonance pillars are connected to the bottom layer, and the second ends of the resonance pillars are disposed to be spaced apart from the top layer, so that the resonance pillars themselves form inductors (L), and capacitors (C) are formed between the resonance pillars and the top layer. Therefore, an inductor-capacitor (LC) filter may be formed in a limited space.

The above descriptions in the summary and the following detailed descriptions are used to demonstrate and explain the spirit and principle of the disclosure and provide a further explanation of the scope of the claims of the disclosure.

### BRIEF DESCRIPTION OF THE DRAWINGS

The disclosure will become better understood from the detailed description given hereinbelow and the accompanying drawings which are given by way of illustration only and thus are not intending to limit the disclosure and wherein:

FIG. 1 illustrates a schematic three-dimensional view of a band-pass filter according to one embodiment of the disclosure;

FIG. 2 illustrates a schematic top view of the band-pass filter in FIG. 1;

FIG. 3 illustrates a schematic right side view of the band-pass filter in FIG. 1;

FIG. 4 illustrates a schematic equivalent circuit diagram of the band-pass filter in FIG. 1;

FIG. 5 illustrates a schematic diagram of insertion loss and return loss with respect to frequency of the band-pass filter in FIG. 1;

FIG. 6 illustrates a schematic three-dimensional view of a band-pass filter according to another embodiment of the disclosure;

FIG. 7 illustrates a schematic top view of the band-pass filter in FIG. 6;

FIG. 8 illustrates a schematic right side view of the band-pass filter in FIG. 6;

FIG. 9 illustrates a schematic equivalent circuit diagram of the band-pass filter in FIG. 6;

FIG. 10 illustrates a schematic diagram of insertion loss and return loss with respect to frequency of the band-pass filter in FIG. 6;

FIG. 11 illustrates a schematic three-dimensional view of a band-pass filter according to another embodiment of the disclosure;

FIG. 12 illustrates a schematic top view of the band-pass filter in FIG. 11;

FIG. 13 illustrates a schematic front cross-sectional view along line A-A of the band-pass filter in FIG. 12;

FIG. 14 illustrates a schematic equivalent circuit diagram of the band-pass filter in FIG. 11;

FIG. 15 illustrates a schematic diagram of insertion loss and return loss with respect to frequency of the band-pass filter in FIG. 11;

FIG. 16 illustrates a schematic three-dimensional view of a band-pass filter according to another embodiment of the disclosure;

FIG. 17 illustrates a schematic top view of the band-pass filter in FIG. 16;

FIG. 18 illustrates a schematic left side view of the band-pass filter in FIG. 16;

FIG. 19 illustrates a schematic equivalent circuit diagram of the band-pass filter in FIG. 16;

FIG. 20 illustrates a schematic diagram of insertion loss and return loss with respect to frequency of the band-pass filter in FIG. 16;

FIG. 21 illustrates a schematic three-dimensional view of a band-pass filter according to another embodiment of the disclosure;

FIG. 22 illustrates a schematic top view of the band-pass filter in FIG. 21;

FIG. 23 illustrates a schematic left side view of the band-pass filter in FIG. 21;

FIG. 24 illustrates a schematic equivalent circuit diagram of the band-pass filter in FIG. 21; and

FIG. 25 illustrates a schematic diagram of insertion loss and return loss with respect to frequency of the band-pass filter in FIG. 21.

### DETAILED DESCRIPTION

Features and advantages of embodiments of the disclosure are described in the following detailed description, it allows the person skilled in the art to understand the technical contents of the embodiments of the disclosure and implement them. Based on the disclosure, the claims, and the drawings, the person skilled in the art can easily comprehend the purposes of the advantages of the disclosure. The following embodiments are further illustrating the perspective of the disclosure, but not intending to limit the scope of the disclosure in any way.

The drawings may not be drawn to actual size, proportions, or angles, some exaggerations may be necessary in order to emphasize basic structural relationships, while some are simplified for clarity of understanding, but the disclosure is not limited thereto. Various modifications may be made without departing from the spirit of the disclosure. In addition, the spatially relative terms, such as “up”, “top”, “above”, “down”, “low”, “left”, “right”, “front”, “rear”, and “back” and the like, may be used herein for ease of description to describe the relationship of one element or feature to another element(s) of feature(s) as illustrated in the drawings. It will be understood that the spatially relative terms are intended to encompass orientations of the element or feature but not intended to limit the disclosure.

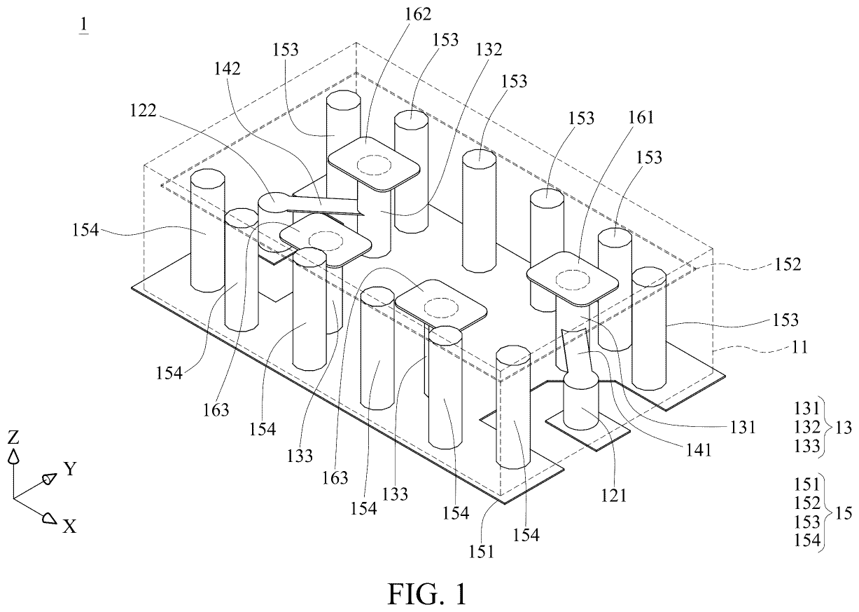

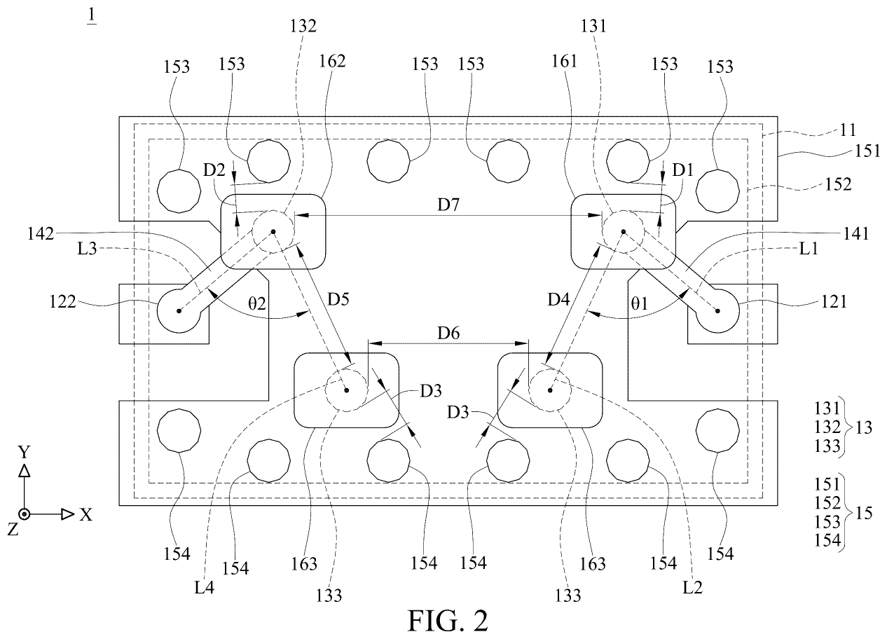

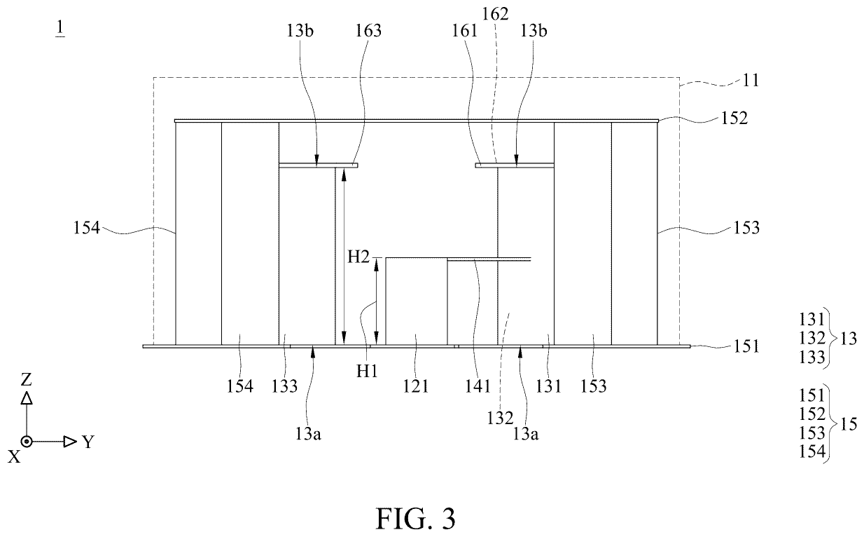

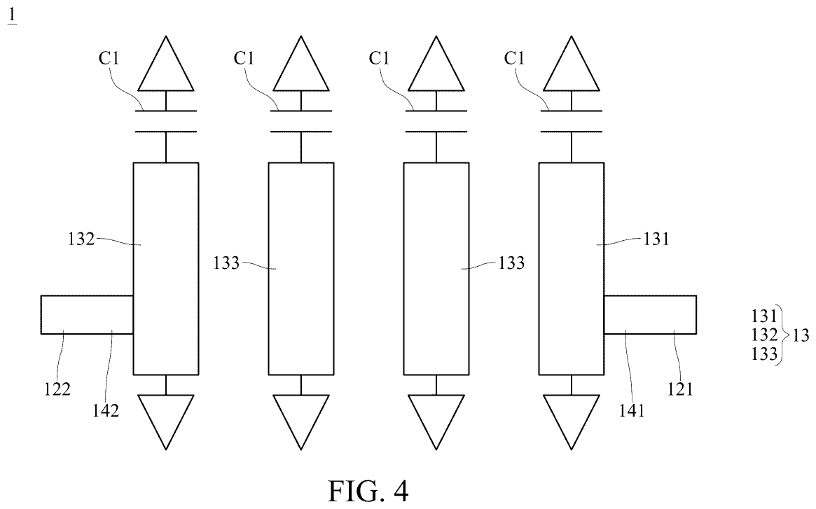

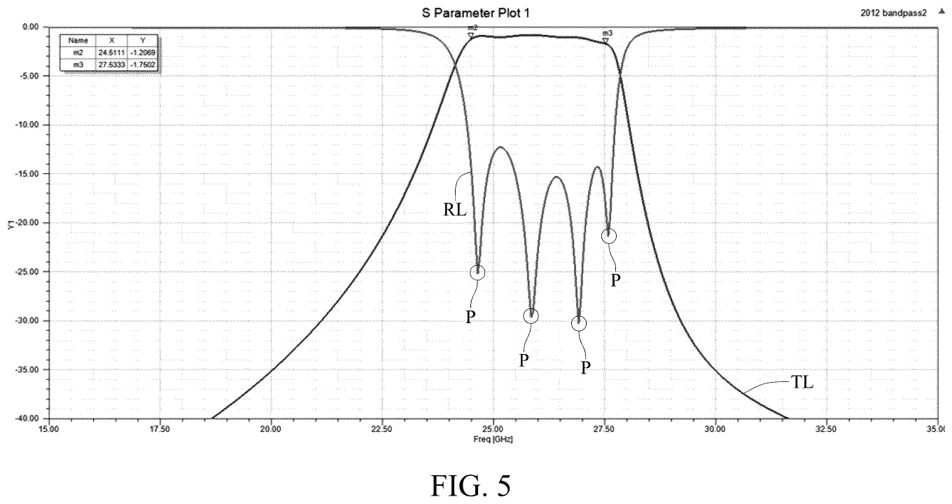

Please refer to FIG. 1 to FIG. 5. FIG. 1 illustrates a schematic three-dimensional view of a band-pass filter according to one embodiment of the disclosure. FIG. 2 illustrates a schematic top view of the band-pass filter in FIG. 1. FIG. 3 illustrates a schematic right side view of the band-pass filter in FIG. 1. FIG. 4 illustrates a schematic equivalent circuit diagram of the band-pass filter in FIG. 1. FIG. 5 illustrates a schematic diagram of insertion loss and return loss with respect to frequency of the band-pass filter in FIG. 1.

As shown in FIG. 1 to FIG. 3, the band-pass filter 1 includes a body 11, two input-output pillars 121, 122, a plurality of resonance pillars 13, two electrical connectors 141, 142, a conductive cage 15 and a plurality of capacitive conductors 161, 162, 163.

The input-output pillar 121 and the input-output pillar 122 are located on two opposite sides of the body 11 in the X direction. The resonance pillars 13 are disposed in the body 11. Each of the resonance pillars 13 has a first end 13a and a second end 13b. The resonance pillars 13 include two input-output resonance pillars 131, 132 and a plurality of intermediate resonance pillars 133. The input-output resonance pillar 131 is disposed adjacent to the input-output pillar 121. The input-output resonance pillar 131 is electrically connected to the input-output pillar 121 through the electrical connector 141. The input-output resonance pillar 132 is disposed adjacent to the input-output pillar 122. The input-output resonance pillar 132 is electrically connected to the input-output pillar 122 through the electrical connector 142. The body 11 is made of an insulating material or a dielectric material. The input-output pillars 121, 122 and the resonance pillars 13 are made of a conductive material.

The resonance pillars 13 are located between the input-output pillar 121 and the input-output pillar 122 in the X direction. Specifically, the input-output pillar 121 is located on the positive X side of the resonance pillars 13, and the input-output pillar 122 is located on the negative X side of the resonance pillars 13. Additionally, the intermediate resonance pillars 133 are located between the input-output resonance pillar 131 and the input-output resonance pillar 132 in the X direction. Specifically, the input-output resonance pillar 131 is located on the positive X side of the intermediate resonance pillars 133, and the input-output resonance pillar 132 is located on the negative X side of the intermediate resonance pillars 133.

The conductive cage 15 is disposed surrounding the resonance pillars 13 with the X direction as the axis. The conductive cage 15 includes a bottom layer 151, a top layer 152 and a plurality of side connectors 153, 154. Two ends of the side connectors 153, 154 are respectively connected to the bottom layer 151 and the top layer 152. The resonance pillars 13 are located between the bottom layer 151 and the top layer 152 in the Z direction. Specifically, the bottom layer 151 is located on the negative Z side of the resonance pillars 13, and the top layer 152 is located on the positive Z side of the resonance pillars 13. The resonance pillars 13 are located between two groups of the side connectors 153, 154 in the Y direction. Specifically, the side connectors 153 are substantially arranged along the X direction and located on the positive Y side of the resonance pillars 13. The side connectors 154 are substantially arranged along the X direction and located on the negative Y side of the resonance pillars 13.

As shown in FIG. 2 and FIG. 3, the first ends 13a of the resonance pillars 13 are connected to the bottom layer 151. The second ends 13b of the resonance pillars 13 are disposed to be spaced apart from the top layer 152. The conductive cage 15 is disposed to be grounded. The input-output pillars 121, 122 are closer to the bottom layer 151 and farther from the top layer 152. A height H1 of each of the input-output pillars 121, 122 is one quarter to one half of a height H2 of each of the input-output resonance pillars 131, 132. The electrical connectors 141, 142 are located between the first ends 13a and the second ends 13b of the resonance pillars 13. The capacitive conductors 161, 162, 163 are disposed in the body 11 and respectively be connected to the second ends 13b of the resonance pillars 13. Specifically, the capacitive conductor 161 is connected to the second end 13b of the input-output resonance pillar 131. The capacitive conductor 162 is connected to the second end 13b of the input-output resonance pillar 132. The capacitive conductors 163 are connected to the second ends 13b of the intermediate resonance pillars 133. The capacitive conductors 161, 162, 163 are disposed to be spaced apart from the top layer 152, thereby forming capacitors.

There are minimum distances D1, D2, D3 between the resonance pillars 13 and the side connectors 153. Specifically, there is the minimum distance D1 between the input-output resonance pillar 131 and one of the side connectors 153, and there is the minimum distance D2 between the input-output resonance pillar 132 and one of the side connectors 153, and there is the minimum distance D3 between one of the intermediate resonance pillars 133 and one of the side connectors 153. There are minimum distances D4, D5 between two of the resonance pillars 13. Specifically, there is the minimum distance D4 between the input-output resonance pillar 131 and the nearest one of the intermediate resonance pillars 133, and there is the minimum distance D5 between the input-output resonance pillar 132 and the nearest one of the intermediate resonance pillars 133. The minimum distance D1 between the input-output resonance pillar 131 and one of the side connectors 153 is less than the minimum distance D4 between the input-output resonance pillar 131 and the nearest one of the intermediate resonance pillars 133, and the minimum distance D1 is less than the minimum distance D5 between the input-output resonance pillar 132 and the nearest one of the intermediate resonance pillars 133. The minimum distance D2 between the input-output resonance pillar 132 and one of the side connectors 153 is less than the minimum distance D4 between the input-output resonance pillar 131 and the nearest one of the intermediate resonance pillars 133, and the minimum distance D2 is less than the minimum distance D5 between the input-output resonance pillar 132 and the nearest one of the intermediate resonance pillars 133. The minimum distance D3 between one of the intermediate resonance pillars 133 and one of the side connectors 153 is less than the minimum distance D4 between the input-output resonance pillar 131 and the nearest one of the intermediate resonance pillars 133, and the minimum distance D3 is less than the minimum distance D5 between the input-output resonance pillar 132 and the nearest one of the intermediate resonance pillars 133.

There is a minimum distance D6 between adjacent two of the intermediate resonance pillars 133. The minimum distance D4 between the input-output resonance pillar 131 and the nearest one of the intermediate resonance pillars 133 is less than the minimum distance D6 between two of the intermediate resonance pillars 133. The minimum distance D5 between the input-output resonance pillar 132 and the nearest one of the intermediate resonance pillars 133 is less than the minimum distance D6 between two of the intermediate resonance pillars 133.

A distance D7 between the input-output resonance pillar 131 and the input-output resonance pillar 132 is greater than the distances D4, D5, D6 between other adjacent two of the resonance pillars 13. Specifically, the distance D7 is greater than the minimum distance D4 between the input-output resonance pillar 131 and one of the intermediate resonance pillars 133. The distance D7 is greater than the minimum distance D5 between the input-output resonance pillar 132 and one of the intermediate resonance pillars 133. The distance D7 is greater than the minimum distance D6 between two of the intermediate resonance pillars 133.

An angle θ1 between a connecting line L1 connecting a center of the input-output resonance pillar 131 to a center of the nearest one of the input-output pillar 121 and a connecting line L2 connecting the center of the input-output resonance pillar 131 to a center of the nearest one of the intermediate resonance pillars 133 is less than 90 degrees. An angle θ2 between a connecting line L3 connecting a center of the input-output resonance pillar 132 to a center of the nearest one of the input-output pillar 122 and a connecting line L4 connecting the center of the input-output resonance pillar 132 to a center of the nearest one of the intermediate resonance pillars 133 is less than 90 degrees. In the band-pass filter 1, the first ends 13a of the resonance pillars 13 are connected to the bottom layer 151, and the second ends 13b are disposed to be spaced apart from the top layer 152, so that the resonance pillars 13 themselves form inductors (L), capacitors (C) are formed between the resonance pillars 13 and the top layer 152, and an inductor-capacitor (LC) filter may be formed in a very small horizontal area and a limited height (that is, a limited space). Thereby, the band-pass filter 1 meets the requirement of miniaturization.

In this embodiment, the resonance pillars 13 are arranged in a trapezoidal shape, but the disclosure is not limited thereto. In other embodiments, the resonance pillars 13 may be arranged in a zigzag shape or other polygonal shapes. Thereby, a required distance of the resonance pillars 13 in the X direction may be reduced.

In this embodiment, the body 11 is made of ceramic. For example, the body 11 may be made of Low-Temperature Co-fired Ceramic (LTCC). Thereby, the body 11 may fill the space among the resonance pillars 13 and the conductive cage 15. But the disclosure is not limited thereto. In other embodiments, the body 11 may also be made of other insulating materials or dielectric materials that may fill the space among the resonance pillars 13 and the conductive cage 15.

In this embodiment, the side connectors 153 are a plurality of connecting pillars, but the disclosure is not limited thereto. In other embodiments, the side connectors 153 may also be two side conductive layers respectively located on the positive Y side and the negative Y side of the resonance pillars 13.

In this embodiment, the band-pass filter 1 is symmetrical with respect to the YZ plane. The input-output pillar 121 and the input-output pillar 122 may be selected one to be input a signal and the other one to output the signal, but the disclosure is not limited thereto. In other embodiments, the band-pass filter may also be asymmetric.

As shown in FIG. 4 and FIG. 5, the band-pass effect of the band-pass filter 1 is illustrated. The capacitors C1 in FIG. 4 are respectively formed by the capacitive conductor 161 and the top layer 152, by the capacitive conductor 162 and the top layer 152, and by the capacitive conductors 163 and the top layer 152 (FIG. 3). In an example, a length of the band-pass filter 1 in the X direction (approximately the distance from the input-output pillar 121 to the input-output pillar 122) is about 2.0 mm. A length of the band-pass filter 1 in the Y direction (approximately the distance from the side connectors 153 to the side connectors 154) is about 1.2 mm. A length of the band-pass filter 1 in the Z direction (approximately the distance from the bottom layer 151 to the top layer 152) is about 0.8 mm. In FIG. 5, line TL is a schematic plot illustrating the insertion loss with respect to frequency, and line RL is a schematic plot illustrating the return loss with respect to frequency. A signal with a certain frequency is input from the input-output pillar 121, an intensity of the signal that may penetrate the band-pass filter 1 and reach the input-output pillar 122 is recorded, signals with different frequencies are scanned and input, and then the line TL is drawn. A signal with a certain frequency is input from the input-output pillar 121, an intensity of the signal that is reflected by the band-pass filter 1 is recorded, signals with different frequencies are scanned and input, and then the line RL is drawn.

As known from FIG. 5, signals with a frequency below about 22.50 GHz are almost reflected by the band-pass filter 1 and may not penetrate the band-pass filter 1. Signals with a frequency about 22.50-24.50 GHz partially penetrate the band-pass filter 1 and are partially reflected by the band-pass filter 1. Most of signals with a frequency about 24.50-27.50 GHz penetrate the band-pass filter 1, a band-pass bandwidth of the band-pass filter 1 is about 3.00 GHz, and a central frequency falls approximately 26.00 GHz. Signals with a frequency about 27.50-28.50 GHz partially penetrate the band-pass filter 1 and are partially reflected by the band-pass filter 1. Signals with a frequency above about 28.50 GHz are almost reflected by the band-pass filter 1 and may not penetrate the band-pass filter 1. In the line RL, there are four points P where the return loss of the signals drops sharply, and the number of the points P matches the number of the resonance pillars 13 (one input-output resonance pillar 131, two intermediate resonance pillars 133 and one input-output resonance pillar 132). It is speculated that the greater the number of the resonance pillars 13 is, the wider band-pass bandwidth of the band-pass filter 1 may be.

In this embodiment, a number of the intermediate resonance pillars 133 is two, but the disclosure is not limited thereto. In other embodiments, the number of the intermediate resonance pillar 133 may also be one, so that the band-pass bandwidth of the band-pass filter 1 may be narrowed. Designers of the band-pass filter 1 may design band-pass filters with different bandwidths and central frequencies according to the requirements.

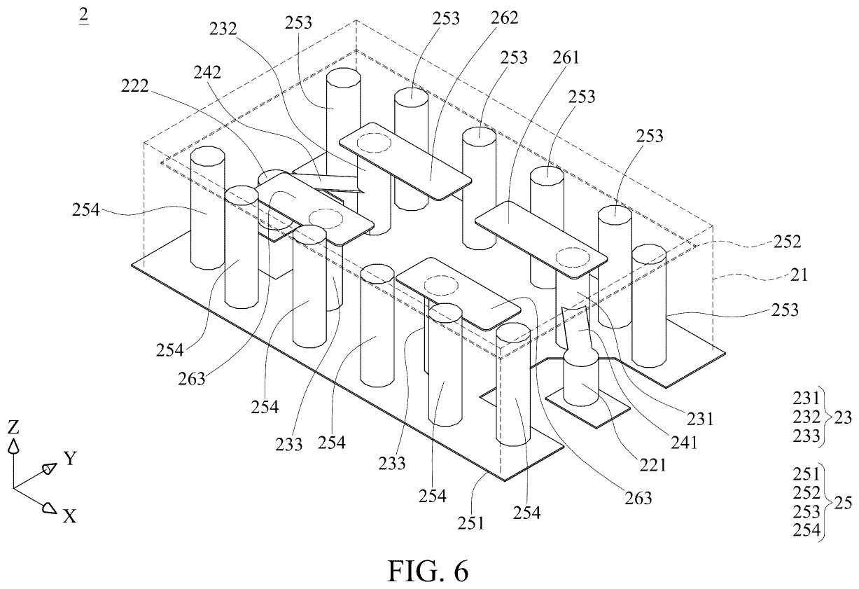

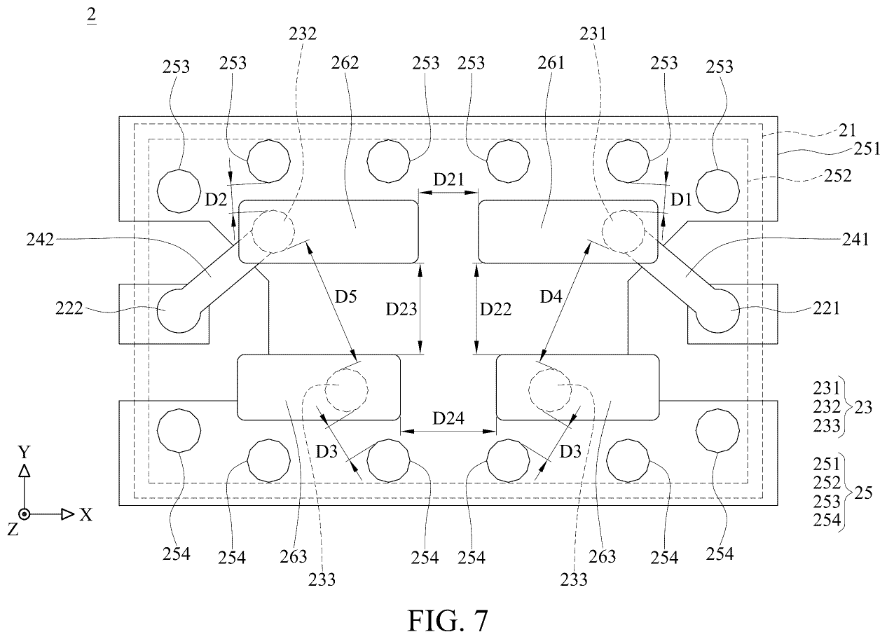

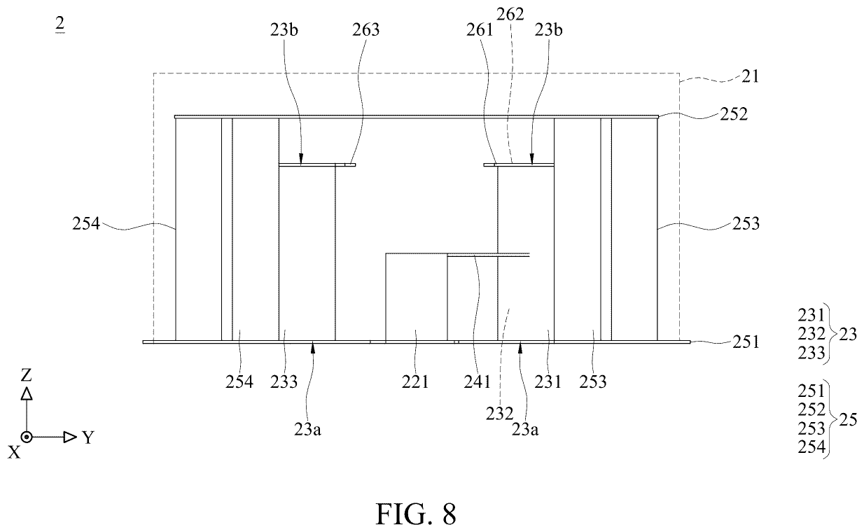

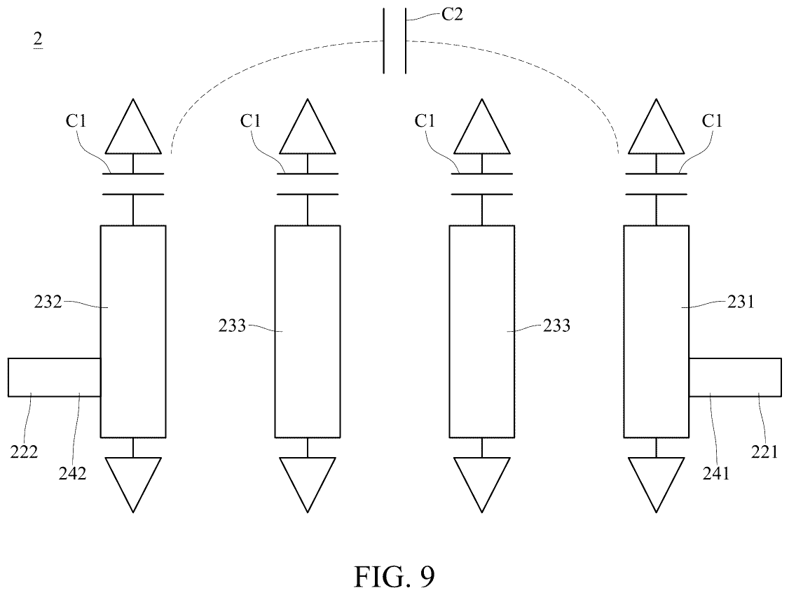

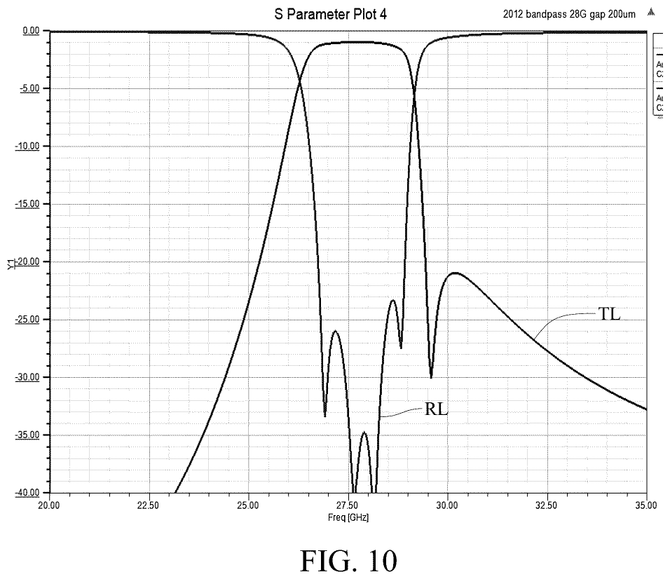

Please refer to FIG. 6 to FIG. 10. FIG. 6 illustrates a schematic three-dimensional view of a band-pass filter according to another embodiment of the disclosure. FIG. 7 illustrates a schematic top view of the band-pass filter in FIG. 6. FIG. 8 illustrates a schematic right side view of the band-pass filter in FIG. 6. FIG. 9 illustrates a schematic equivalent circuit diagram of the band-pass filter in FIG. 6. FIG. 10 illustrates a schematic diagram of insertion loss and return loss with respect to frequency of the band-pass filter in FIG. 6.

As shown in FIG. 6 to FIG. 8, the band-pass filter 2 is similar to the band-pass filter 1 as shown in FIG. 1 to FIG. 3. The band-pass filter 2 includes a body 21, two input-output pillars 221, 222, a plurality of resonance pillars 23, two electrical connectors 241, 242, a conductive cage 25 and a plurality of capacitive conductors 261, 262, 263.

The input-output pillar 221 and the input-output pillar 222 are located on two opposite sides of the body 21 in the X direction. The resonance pillars 23 are disposed in the body 21. Each of the resonance pillars 23 has a first end 23a and a second end 23b. The resonance pillars 23 include two input-output resonance pillars 231, 232 and a plurality of intermediate resonance pillars 233. The input-output resonance pillar 231 is electrically connected to the input-output pillar 221 through the electrical connector 241. The input-output resonance pillar 232 is electrically connected to the input-output pillar 222 through the electrical connector 242. The resonance pillars 23 are located between the input-output pillar 221 and the input-output pillar 222 in the X direction. The conductive cage 25 is disposed surrounding the resonance pillars 23 with the X direction as the axis. The conductive cage 25 includes a bottom layer 251, a top layer 252 and a plurality of side connectors 253, 254. Two ends of the side connectors 253, 254 are respectively connected to the bottom layer 251 and the top layer 252. The resonance pillars 23 are located between the bottom layer 251 and the top layer 252 and between the side connectors 253 and the side connectors 254.

As shown in FIG. 7 and FIG. 8, the first ends 23a of the resonance pillars 23 are connected to the bottom layer 251. The second ends 23b of the resonance pillars 23 are disposed to be spaced apart from the top layer 252. The conductive cage 25 is disposed to be grounded. The capacitive conductors 261, 262, 263 are disposed in the body 21 and respectively connected to the second ends 23b of the resonance pillars 23. The capacitive conductors 261, 262, 263 are disposed to be spaced apart from the top layer 252, thereby forming capacitors. The minimum distance D1 from the input-output resonance pillar 231 to one of the side connectors 253, the minimum distance D2 from the input-output resonance pillar 232 to one of the side connectors 253, and the minimum distance D3 from one of the intermediate resonance pillars 233 to one of the side connectors 253 are all less than the minimum distances D4, D5 between two of the resonance pillars 23.

The band-pass filter 2 in this embodiment further has features as following. Among the capacitive conductors 261, 262, 263, a distance D21 between the capacitive conductor 261 connected to the input-output resonance pillar 231 and the capacitive conductor 262 connected to the input-output resonance pillar 232 is less than the minimum distances D4, D5 between two of the resonance pillars 23. Additionally, the distance D21 is also less than a distance D22 between the capacitive conductor 261 connected to the input-output resonance pillar 231 and one of the capacitive conductors 263 connected to one of the intermediate resonance pillars 233. The distance D21 is also less than a distance D23 between the capacitive conductor 262 connected to the input-output resonance pillar 232 and one of the capacitive conductors 263 connected to one of the intermediate resonance pillars 233. The distance D21 is also less than a distance D24 between two of the capacitive conductors 263 connected to the intermediate resonance pillars 233. Thereby, a capacitor may be formed between the capacitive conductor 261 and the capacitive conductor 262. A capacitor may not be formed between the capacitive conductor 261 and one of the capacitive conductors 263 since the distance D22 is greater than the distance D21. A capacitor may not be formed between the capacitive conductor 262 and one of the capacitive conductors 263 since the distance D23 is greater than the distance D21. A capacitor may not be formed between two of the capacitive conductors 263 since the distance D24 is greater than the distance D21.

As shown in FIG. 9 and FIG. 10, the band-pass effect of the band-pass filter 2 is illustrated. The capacitors C1 in FIG. 9 are respectively formed by the capacitive conductor 261 and the top layer 252, by the capacitive conductor 262 and the top layer 252, and by the capacitive conductors 263 and the top layer 252 (FIG. 8). The capacitor C2 is formed by the capacitive conductor 261 and the capacitive conductor 262 (FIG. 7).

In FIG. 10, line TL is a schematic plot illustrating the insertion loss with respect to frequency, and line RL is a schematic plot illustrating the return loss with respect to frequency. As known from FIG. 10, signals with a frequency below about 24.0 GHz are almost reflected by the band-pass filter 2 and may not penetrate the band-pass filter 2. Signals with a frequency about 24.0-26.0 GHz partially penetrate the band-pass filter 2 and are partially reflected by the band-pass filter 2. Most of signals with a frequency about 26.0-29.0 GHz penetrate the band-pass filter 2, a band-pass bandwidth of the band-pass filter 2 is about 3.00 GHz, and a central frequency falls approximately 27.5 GHz. Signals with a frequency about 29.0-29.50 GHz partially penetrate the band-pass filter 2 and partially reflected by the band-pass filter 2. Signals with a frequency above about 29.50 GHz are almost reflected by the band-pass filter 2 and may not penetrate the band-pass filter 2. It may be seen that in the higher frequency band (29.0-29.50 GHZ) where “the signals partially penetrate the band-pass filter 2 and are partially reflected by the band-pass filter 2”, the bandwidth is about 0.5 GHZ. In FIG. 5, in the higher frequency band where “the signals partially penetrate the band-pass filter 1 and are partially reflected by the band-pass filter 1”, the bandwidth is about 1.00 GHz. Therefore, compared with the band-pass filter 1 in FIG. 5, a frequency band of the band-pass filter 2 in this embodiment where “the signals partially penetrate the band-pass filter 2 and are partially reflected by the band-pass filter 2”, i.e. “difficult to be distinguished whether the signals penetrate or not”, is narrowed.

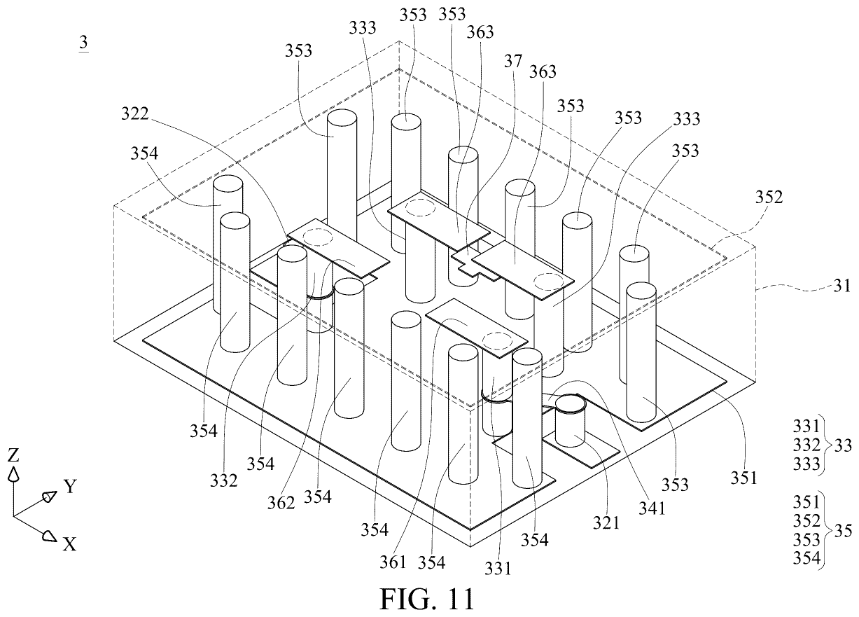

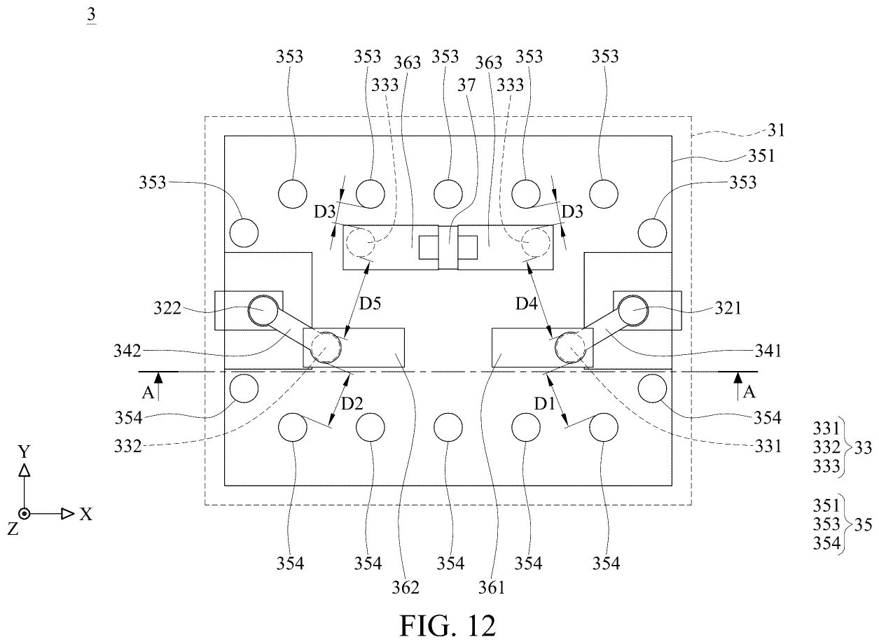

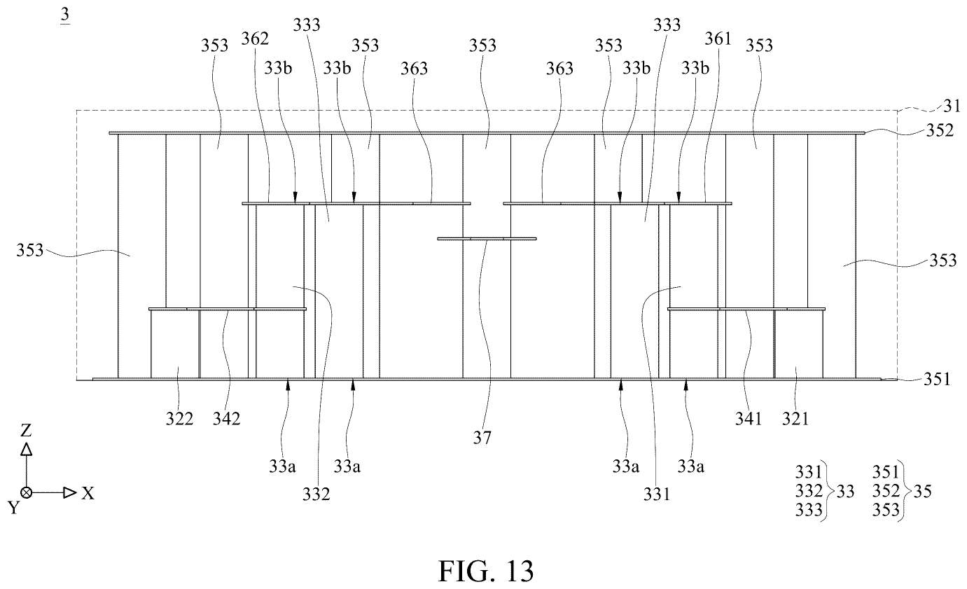

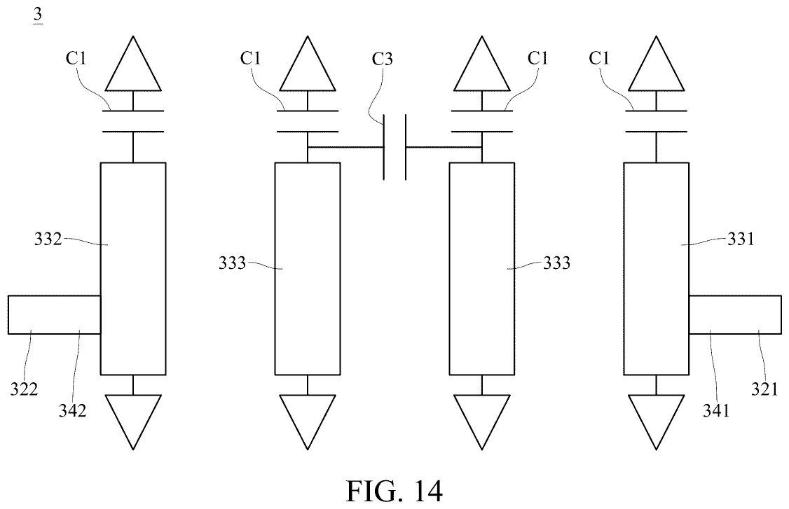

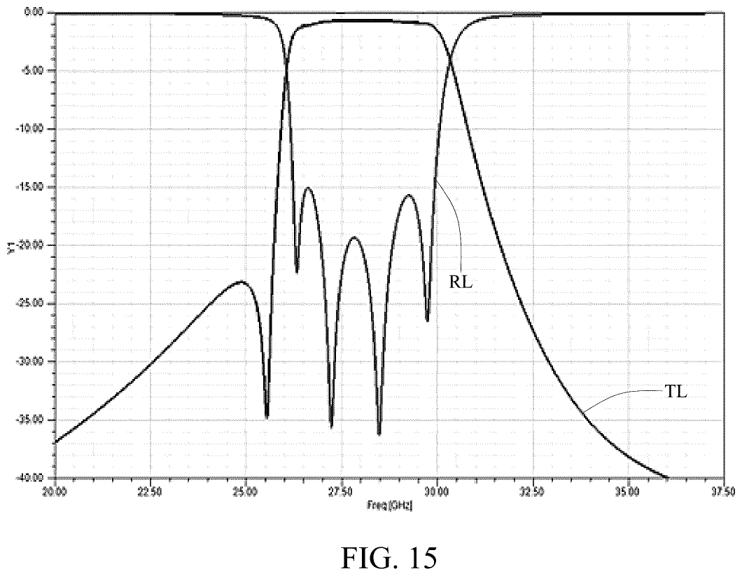

Please refer to FIG. 11 to FIG. 15. FIG. 11 illustrates a schematic three-dimensional view of a band-pass filter according to another embodiment of the disclosure. FIG. 12 illustrates a schematic top view of the band-pass filter in FIG. 11. FIG. 13 illustrates a schematic front cross-sectional view along line A-A of the band-pass filter in FIG. 12. FIG. 14 illustrates a schematic equivalent circuit diagram of the band-pass filter in FIG. 11. FIG. 15 illustrates a schematic diagram of insertion loss and return loss with respect to frequency of the band-pass filter in FIG. 11.

As shown in FIG. 11 to FIG. 13, the band-pass filter 3 is similar to the band-pass filter 1 as shown in FIG. 1 to FIG. 3. The band-pass filter 3 includes a body 31, two input-output pillars 321, 322, a plurality of resonance pillars 33, two electrical connectors 341, 342, a conductive cage 35 and a plurality of capacitive conductors 361, 362, 363.

The input-output pillar 321 and the input-output pillar 322 are located on two opposite sides of the body 31 in the X direction. The resonance pillars 33 are disposed in the body 31. Each of the resonance pillars 33 has a first end 33a and a second end 33b. The resonance pillars 33 include two input-output resonance pillars 331, 332 and a plurality of intermediate resonance pillars 333. The input-output resonance pillar 331 is electrically connected to the input-output pillar 321 through the electrical connector 341. The input-output resonance pillar 332 is electrically connected to the input-output pillar 322 through the electrical connector 342. The resonance pillars 33 are located between the input-output pillar 321 and the input-output pillar 322 in the X direction. The conductive cage 35 is disposed surrounding the resonance pillars 33 with the X direction as the axis. The conductive cage 35 includes a bottom layer 351, a top layer 352 and a plurality of side connectors 353, 354. Two ends of the side connectors 353, 354 are respectively connected to the bottom layer 351 and the top layer 352. The resonance pillars 33 are located between the bottom layer 351 and the top layer 352 and between the side connectors 353 and the side connectors 354.

As shown in FIG. 12 and FIG. 13, the first ends 33a of the resonance pillars 33 are connected to the bottom layer 351. The second ends 33b of the resonance pillars 33 are disposed to be spaced apart from the top layer 352. The conductive cage 35 is disposed to be grounded. The capacitive conductors 361, 362, 363 are disposed in the body 31 and respectively connected to the second ends 33b of the resonance pillars 33. The capacitive conductors 361, 362, 363 are disposed to be spaced apart from the top layer 352, thereby forming capacitors. The minimum distance D1 from the input-output resonance pillar 331 to one of the side connectors 353, the minimum distance D2 from the input-output resonance pillar 332 to one of the side connectors 353, and the minimum distance D3 from one of the intermediate resonance pillars 333 to one of the side connectors 353 are all less than the minimum distances D4, D5 between two of the resonance pillars 33.

The band-pass filter 3 in this embodiment further has features as following. The band-pass filter 3 further includes a floating conductor 37. The capacitive conductors 363 connected to the intermediate resonance pillars 333 are adjacent to each other. The floating conductor 37 is disposed to overlap with and be spaced apart from adjacent two of the capacitive conductors 363. The floating conductor 37 is disposed between the first ends 33a and the second ends 33b of the resonance pillars 33. The floating conductor 37 is disposed closer to the second ends 33b and farther from the first ends 33a. The floating conductor 37 is not electrically connected to any element and is electrically floating. Thereby, one of the capacitive conductors 363, the floating conductor 37 and the other one of the capacitive conductors 363 may form a capacitor.

As shown in FIG. 14 and FIG. 15, the band-pass effect of the band-pass filter 3 is illustrated. The capacitors C1 in FIG. 14 are respectively formed by the capacitive conductor 361 and the top layer 352, by the capacitive conductor 362 and the top layer 352, and by the capacitive conductors 363 and the top layer 352 (FIG. 13). The capacitor C3 is formed by one of the capacitive conductor 363, the floating conductor 37 and the other one of the capacitive conductor 363 (FIG. 13).

In FIG. 15, line TL is a schematic plot illustrating the insertion loss with respect to frequency, and line RL is a schematic plot illustrating the return loss with respect to frequency. As known from FIG. 15, signals with a frequency below about 25.75 GHz are almost reflected by the band-pass filter 3 and may not penetrate the band-pass filter 3. Signals with a frequency about 25.75-26.25 GHz partially penetrate the band-pass filter 3 and are partially reflected by the band-pass filter 3. Most of signals with a frequency about 26.25-29.75 GHz penetrate the band-pass filter 3, a band-pass bandwidth of the band-pass filter 3 is about 3.50 GHz, and a central frequency falls approximately 28.00 GHz. Signals with a frequency about 29.75-31.25 GHz partially penetrate the band-pass filter 3 and are partially reflected by the band-pass filter 3. Signals with a frequency above about 31.25 GHz are almost reflected by the band-pass filter 3 and may not penetrate the band-pass filter 3. It may be seen that in the lower frequency band (25.75-26.25 GHz) where “the signals partially penetrate the band-pass filter 3 and are partially reflected by the band-pass filter 3”, the bandwidth is about 0.5 GHZ. In FIG. 5, in the lower frequency band where “the signals partially penetrate the band-pass filter 1 and are partially reflected by the band-pass filter 1”, the bandwidth is about 2.00 GHz. Therefore, compared with the band-pass filter 1 in FIG. 5, a frequency band of the band-pass filter 3 in this embodiment where “the signals partially penetrate the band-pass filter 3 and are partially reflected by the band-pass filter 3”, i.e. “difficult to be distinguished whether the signals penetrate or not”, is narrowed.

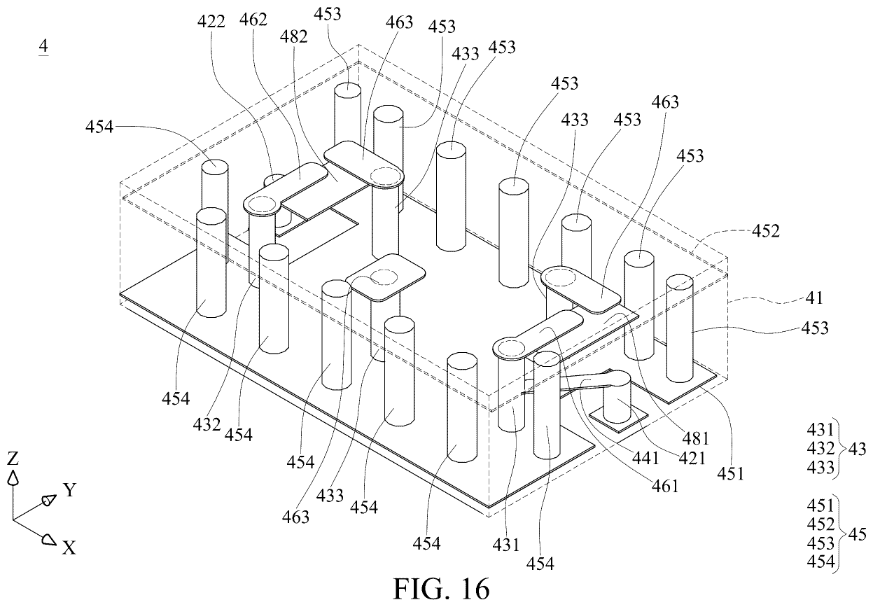

Please refer to FIG. 16 to FIG. 20. FIG. 16 illustrates a schematic three-dimensional view of a band-pass filter according to another embodiment of the disclosure.

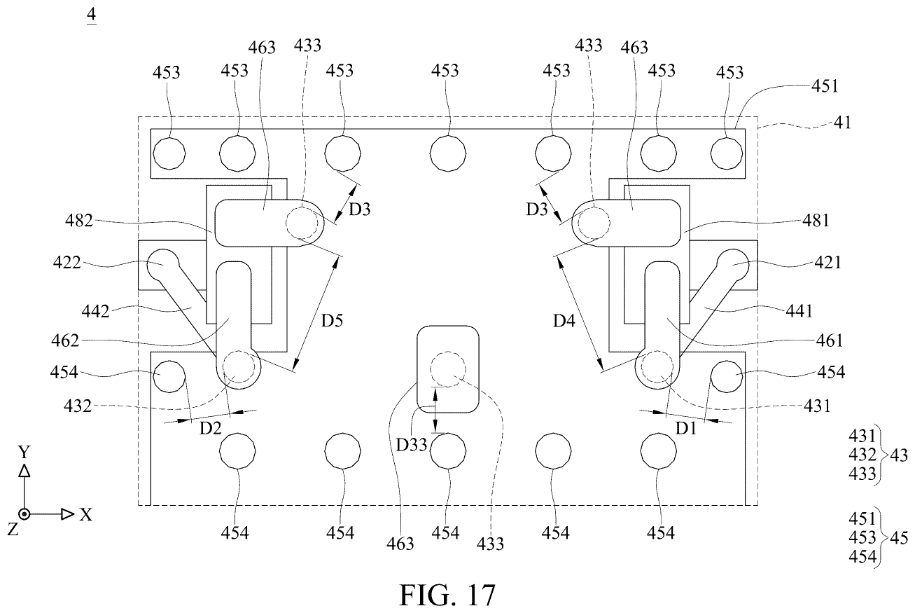

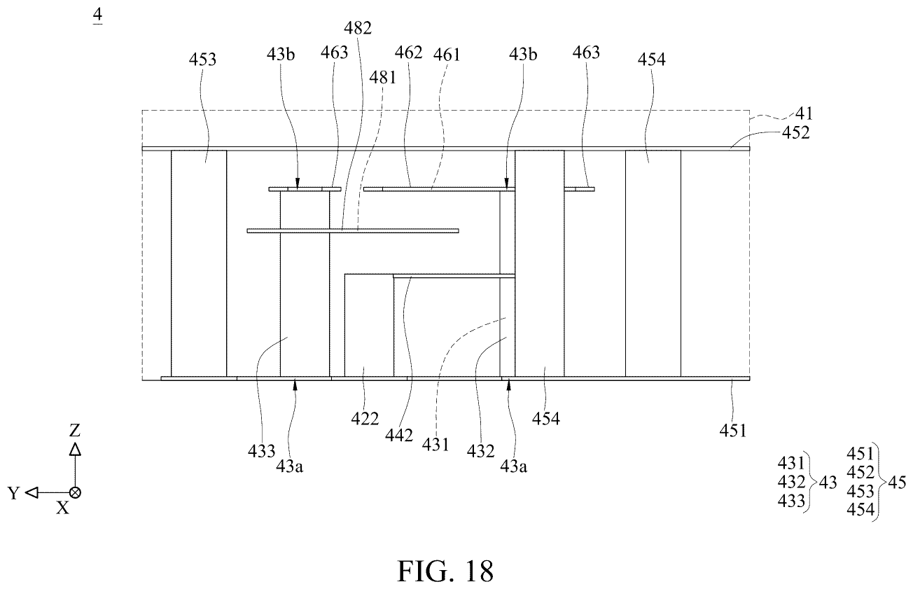

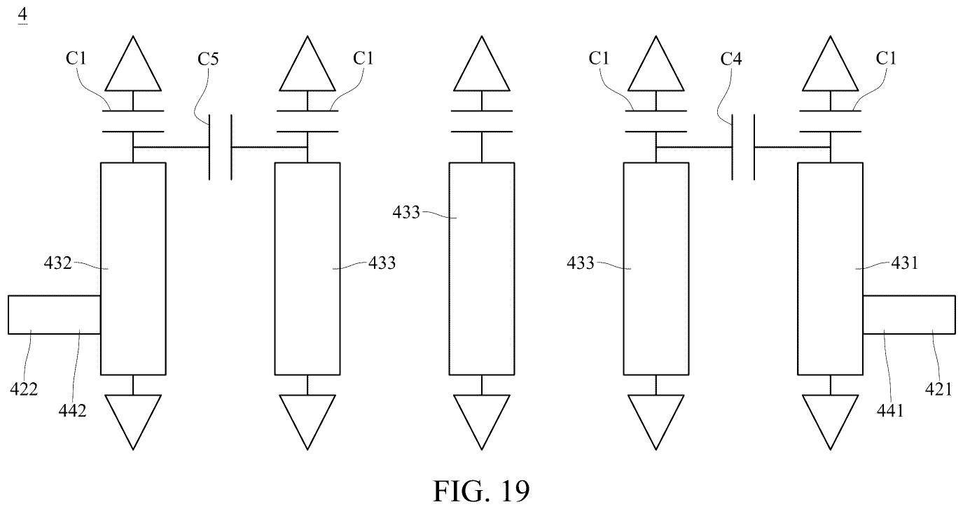

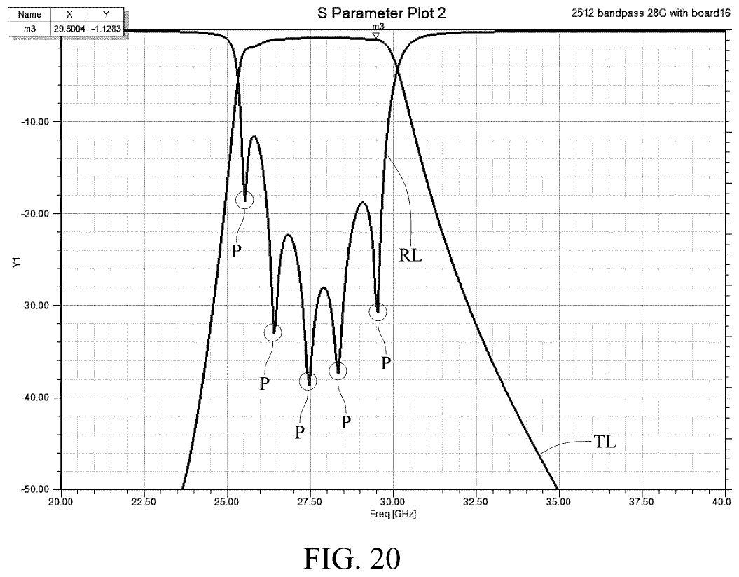

FIG. 17 illustrates a schematic top view of the band-pass filter in FIG. 16. FIG. 18 illustrates a schematic left side view of the band-pass filter in FIG. 16. FIG. 19 illustrates a schematic equivalent circuit diagram of the band-pass filter in FIG. 16. FIG. 20 illustrates a schematic diagram of insertion loss and return loss with respect to frequency of the band-pass filter in FIG. 16.

As shown in FIG. 16 to FIG. 18, the band-pass filter 4 is similar to the band-pass filter 1 as shown in FIG. 1 to FIG. 3. The band-pass filter 4 includes a body 41, two input-output pillars 421, 422, a plurality of resonance pillars 43, two electrical connectors 441, 442, a conductive cage 45 and a plurality of capacitive conductors 461, 462, 463.

The input-output pillar 421 and the input-output pillar 422 are located on two opposite sides of the body 41 in the X direction. The resonance pillars 43 are disposed in the body 41. Each of the resonance pillars 43 has a first end 43a and a second end 43b. The resonance pillars 43 include two input-output resonance pillars 431, 432 and a plurality of intermediate resonance pillars 433. The input-output resonance pillar 431 is electrically connected to the input-output pillar 421 through the electrical connector 441. The input-output resonance pillar 432 is electrically connected to the input-output pillar 422 through the electrical connector 442. The resonance pillars 43 are located between the input-output pillar 421 and the input-output pillar 422 in the X direction. The conductive cage 45 is disposed surrounding the resonance pillars 43 with the X direction as the axis. The conductive cage 45 includes a bottom layer 451, a top layer 452 and a plurality of side connectors 453, 454. Two ends of the side connectors 453, 454 are respectively connected to the bottom layer 451 and the top layer 452. The resonance pillars 43 are located between the bottom layer 451 and the top layer 452, and between the side connectors 453 and the side connectors 454. In this embodiment, the resonance pillars 43 are arranged in a zigzag shape.

As shown in FIG. 17 and FIG. 18, the first ends 43a of the resonance pillars 43 are connected to the bottom layer 451. The second ends 43b of the resonance pillars 43 are disposed to be spaced apart from the top layer 452. The conductive cage 45 is disposed to be grounded. The capacitive conductors 461, 462, 463 are disposed in the body 41 and respectively connected to the second ends 43b of the resonance pillars 43.

The capacitive conductors 461, 462, 463 are disposed to be spaced apart from the top layer 452, thereby forming capacitors. The minimum distance D1 between the input-output resonance pillar 431 and the side connectors 453, the minimum distance D2 between the input-output resonance pillar 432 and the side connectors 453 and the minimum distances D3, D33 between the intermediate resonance pillars 433 and the side connectors 453 are all less than the minimum distances D4, D5 between two of the resonance pillars 43.

The band-pass filter 4 in this embodiment further has features as following. The band-pass filter 4 further includes two floating conductors 481, 482. The capacitive conductor 461 connected to the input-output resonance pillar 431 and one of the capacitive conductors 463 connected to one of the intermediate resonance pillars 433 are adjacent to each other. The floating conductor 481 is disposed to overlap with and be spaced apart from the capacitive conductor 461 and the nearest one of the capacitive conductors 463. The capacitive conductor 462 connected to the input-output resonance pillar 432 and one of the capacitive conductors 463 connected to one of the intermediate resonance pillars 433 are adjacent to each other. The floating conductor 482 is disposed to overlap with and be spaced apart from the capacitive conductor 462 and the nearest one of the capacitive conductors 463. The floating conductors 481, 482 are disposed between the first ends 43a and the second ends 43b of the resonance pillars 43. The floating conductors 481, 482 are disposed closer to the second ends 43b and farther from the first ends 43a. The floating conductors 481, 482 are not electrically connected to any element and is electrically floating. Thereby, the capacitive conductor 461, the floating conductor 481 and the nearest one of the capacitive conductors 463 may form a capacitor. The capacitive conductor 462, the floating conductor 482 and the nearest one of the capacitive conductors 463 may form a capacitor.

As shown in FIG. 19 and FIG. 20, the band-pass effect of the band-pass filter 4 is illustrated. The capacitors C1 in FIG. 19 are respectively formed by the capacitive conductor 461 and the top layer 452, by the capacitive conductor 462 and the top layer 452, and by the capacitive conductors 463 and the top layer 452 (FIG. 18). The capacitor C4 is formed by the capacitive conductor 461, the floating conductor 481 and one of the capacitive conductors 463 (FIG. 18). The capacitors C5 is formed by the capacitive conductor 462, the floating conductor 482 and one of the capacitive conductors 463 (FIG. 18).

In FIG. 20, line TL is a schematic plot illustrating the insertion loss with respect to frequency, and line RL is a schematic plot illustrating the return loss with respect to frequency. As known from FIG. 20, signals with a frequency below about 24.90 GHz are almost reflected by the band-pass filter 4 and may not penetrate the band-pass filter 4. Signals with a frequency about 24.90-25.50 GHz partially penetrate the band-pass filter 4 and are partially reflected by the band-pass filter 4. Most of signals with a frequency about 25.50-29.50 GHz penetrate the band-pass filter 4, a band-pass bandwidth of the band-pass filter 4 is about 4.00 GHz, and a central frequency falls approximately 27.50 GHz. Signals with a frequency about 29.50-31.25 GHz partially penetrate the band-pass filter 4 and are partially reflected by the band-pass filter 4. Signals with a frequency above about 31.25 GHz are almost reflected by the band-pass filter 4 and may not penetrate the band-pass filter 4. It may be seen that the band-pass bandwidth of the band-pass filter 4 is about 4.00 GHz. In FIG. 5, the bandwidth of the band-pass filter 1 is about 3.00 GHz. Therefore, compared with the band-pass filter 1 in FIG. 5, the bandwidth of the band-pass filter 4 in this embodiment is widened. In the line RL, there are five points P where the return loss of the signals drops sharply, and the number of the points P matches the number of the resonance pillars 43 (one input-output resonance pillar 431, three intermediate resonance pillars 433 and one input-output resonance pillar 432). It is speculated that the greater the number of the resonance pillars 43 is, the wider band-pass bandwidth of the band-pass filter 4 may be.

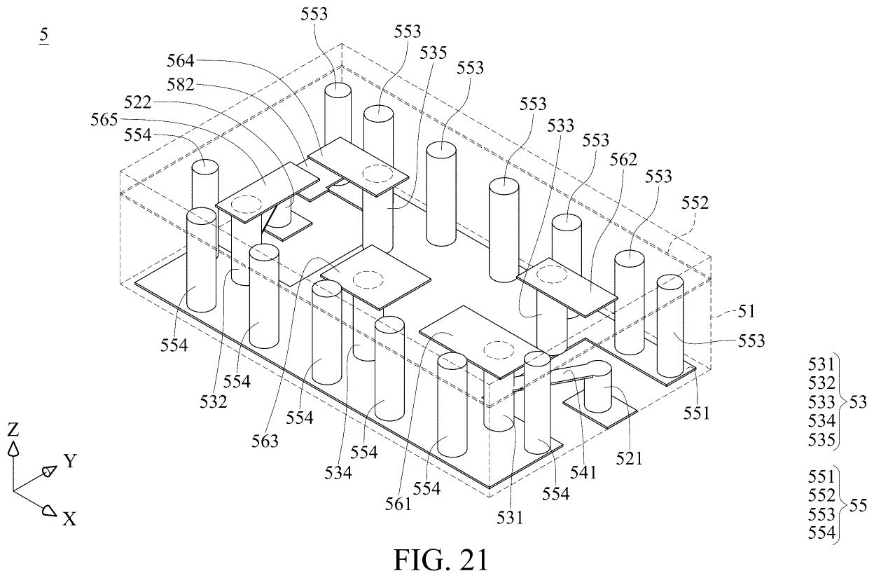

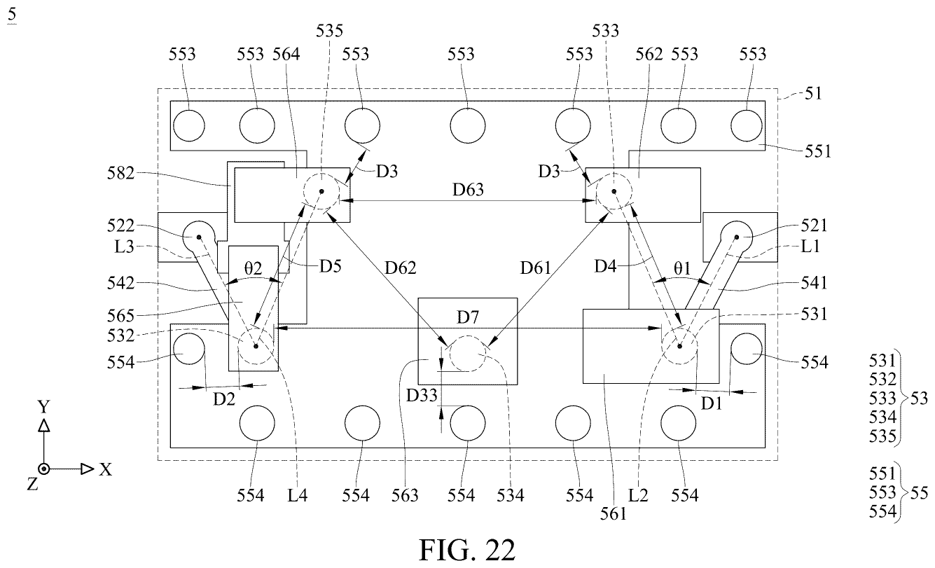

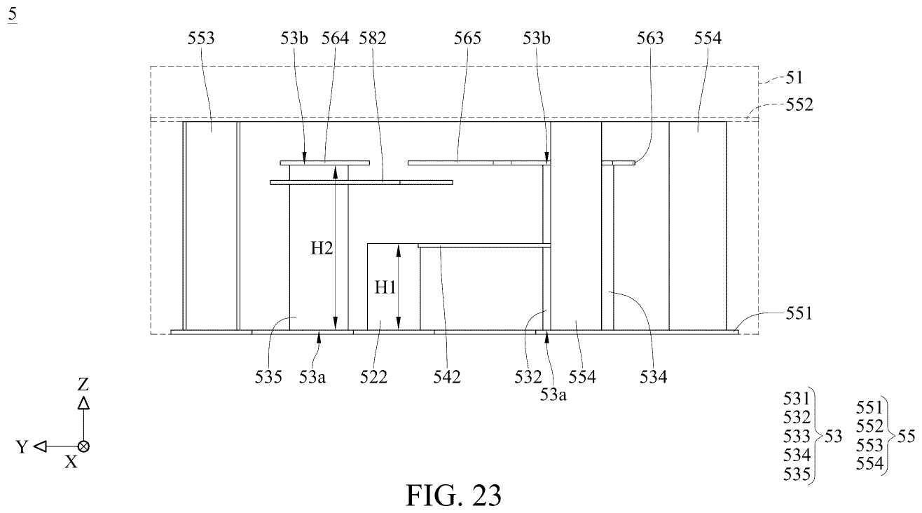

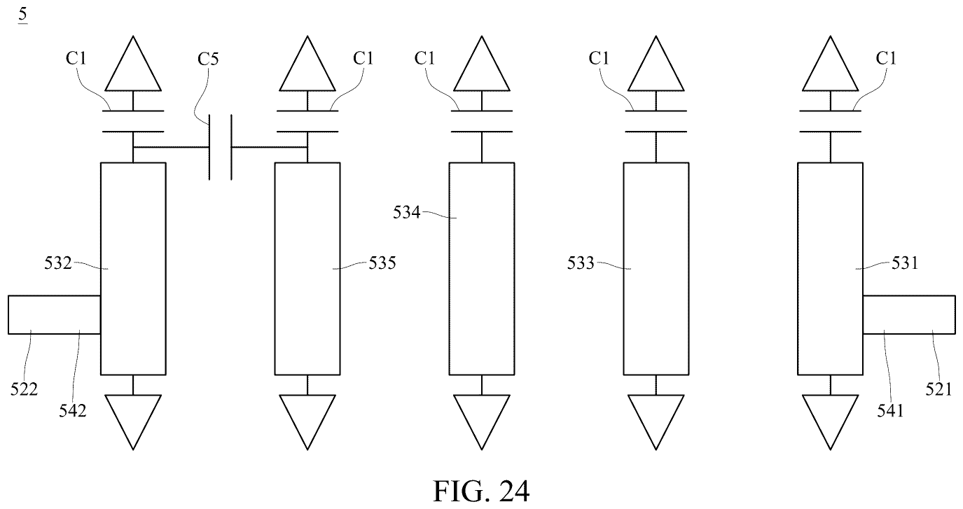

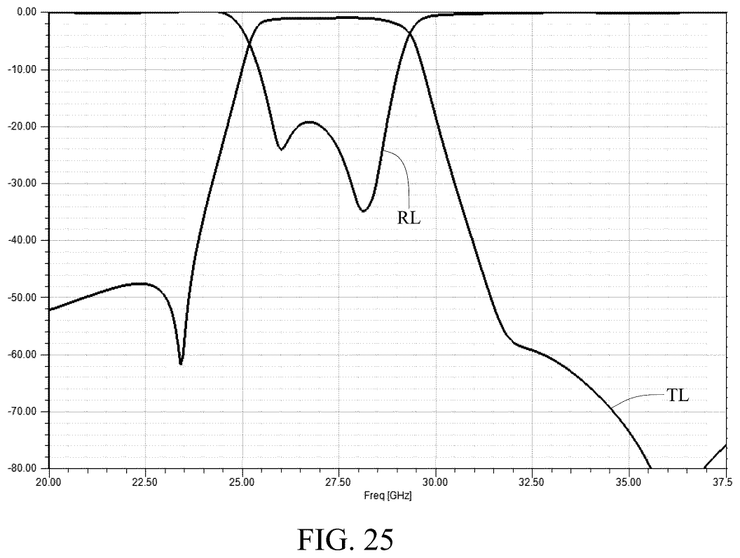

Please refer to FIG. 21 to FIG. 25. FIG. 21 illustrates a schematic three-dimensional view of a band-pass filter according to another embodiment of the disclosure. FIG. 22 illustrates a schematic top view of the band-pass filter in FIG. 21. FIG. 23 illustrates a schematic left side view of the band-pass filter in FIG. 21. FIG. 24 illustrates a schematic equivalent circuit diagram of the band-pass filter in FIG. 21. FIG. 25 illustrates a schematic diagram of insertion loss and return loss with respect to frequency of the band-pass filter in FIG. 21.

As shown in FIG. 21 to FIG. 23, the band-pass filter 5 is similar to the band-pass filter 4 as shown in FIG. 16 to FIG. 20. The band-pass filter 5 includes a body 51, two input-output pillars 521, 522, a plurality of resonance pillars 53, two electrical connectors 541, 542, a conductive cage 55, a first capacitive conductor 561, a second capacitive conductor 562, a third capacitive conductor 563, a fourth capacitive conductor 564 and a fifth capacitive conductor 565.

The input-output pillar 521 and the input-output pillar 522 are located on two opposite sides of the body 51 in the X direction. The resonance pillars 53 are disposed in the body 51. Each of the resonance pillars 53 has a first end 53a and a second end 53b. The resonance pillars 53 include two input-output resonance pillars 531, 532, a first intermediate resonance pillar 533, a second intermediate resonance pillar 534 and a third intermediate resonance pillar 535. The input-output resonance pillar 531 is disposed adjacent to the input-output pillar 521. The input-output resonance pillar 531 is electrically connected to the input-output pillar 521 through the electrical connector 541. The input-output resonance pillar 532 is disposed adjacent to the input-output pillar 522. The input-output resonance pillar 532 is electrically connected to the input-output pillar 522 through the electrical connector 542. The body 51 is made of an insulating material or a dielectric material. The input-output pillars 521, 522 and the resonance pillars 53 are made of a conductive material.

The resonance pillars 53 are located between the input-output pillar 521 and the input-output pillar 522 in the X direction. That is, the projection of the resonance pillars 53 on the X direction is located between the projection of the input-output pillar 521 on the X direction and the projection of the input-output pillar 522 on the X direction. Specifically, the input-output pillar 521 is located on the positive X side of the resonance pillars 53, and the input-output pillar 522 is located on the negative X side of the resonance pillars 53. Additionally, the first intermediate resonance pillar 533, the second intermediate resonance pillar 534 and the third intermediate resonance pillar 535 are located between the input-output resonance pillar 531 and the input-output resonance pillar 532 in the X direction. Specifically, the input-output resonance pillar 531 is located on the positive X side of the first intermediate resonance pillar 533, the second intermediate resonance pillar 534 and the third intermediate resonance pillar 535, and input-output resonance pillar 532 is located on the negative X side of the first intermediate resonance pillar 533, the second intermediate resonance pillar 534 and the third intermediate resonance pillar 535.

The conductive cage 55 is disposed surrounding the resonance pillars 53 with the X direction as the axis. The conductive cage 55 includes a bottom layer 551, a top layer 552 and a plurality of side connectors 553, 554. Two ends of the side connectors 553, 554 are respectively connected to the bottom layer 551 and the top layer 552. The resonance pillars 53 are located between the bottom layer 551 and the top layer 552 in the Z direction. Specifically, the bottom layer 551 is located on the negative Z side of the resonance pillars 53, and the top layer 552 is located on the positive Z side of the resonance pillars 53. The resonance pillars 53 are located between the side connectors 553 and the side connectors 554 in the Y direction. In this embodiment, the resonance pillars 53 are arranged in a zigzag shape.

As shown in FIG. 22 and FIG. 23, the first ends 53a of the resonance pillars 53 are connected to the bottom layer 551. The second ends 53b of the resonance pillars 53 are disposed to be spaced apart from the top layer 552. The conductive cage 55 is disposed to be grounded. The input-output pillars 521, 522 are closer to the bottom layer 551 and farther from the top layer 552. A height H1 of each of the input-output pillars 521, 522 is one quarter to one half of a height H2 of each of the input-output resonance pillars 531, 532. The electrical connectors 541, 542 are located between the first ends 53a and the second ends 53b of the resonance pillars 53.

The first capacitive conductor 561, the second capacitive conductor 562, the third capacitive conductor 563, the fourth capacitive conductor 564 and the fifth capacitive conductor 565 are disposed in the body 51 and respectively connected to the second ends 53b of the resonance pillars 53. Specifically, the first capacitive conductor 561 is connected to the second end 53b of the input-output resonance pillar 531. The second capacitive conductor 562 is connected to the second end 53b of the first intermediate resonance pillar 533. The third capacitive conductor 563 is connected to the second end 53b of the second intermediate resonance pillar 534. The fourth capacitive conductor 564 is connected to the second end 53b of the third intermediate resonance pillar 535. The fifth capacitive conductor 565 is connected to the second end 53b of the input-output resonance pillar 532. The first capacitive conductor 561, the second capacitive conductor 562, the third capacitive conductor 563, the fourth capacitive conductor 564 and the fifth capacitive conductor 565 are disposed to be spaced apart from the top layer 552, thereby forming capacitors.

The minimum distance D1 from the input-output resonance pillar 531 to one of the side connectors 554, the minimum distance D2 from the input-output resonance pillar 532 to one of the side connectors 554, the minimum distance D3 from the first intermediate resonance pillar 533 to one of the side connectors 553, the minimum distance D33 from the second intermediate resonance pillar 534 to one of the side connectors 554, to the minimum distance D3 from the third intermediate resonance pillar 535 to one of the side connectors 553 are all less than the minimum distances D4, D5 between two of the resonance pillars 53.

There is a minimum distance D61 between the first intermediate resonance pillar 533 and the second intermediate resonance pillar 534. There is a minimum distance D62 between the second intermediate resonance pillar 534 and the third intermediate resonance pillar 535. There is a minimum distance D63 between the first intermediate resonance pillar 533 and the third intermediate resonance pillar 535. The minimum distance D4 between the input-output resonance pillar 531 and the first intermediate resonance pillar 533 is less than the minimum distances D61, D62, D63. The minimum distance D5 between the input-output resonance pillar 532 and the third intermediate resonance pillar 535 is less than the minimum distances D61, D62, D63.

A distance D7 between the input-output resonance pillar 531 and the input-output resonance pillar 532 is greater than the distances D4, D5, D61, D62, D63.

An angle θ1 between a connecting line L1 connecting a center of the input-output resonance pillar 531 to a center of the nearest one of the input-output pillar 521 and a connecting line L2 connecting the center of the input-output resonance pillar 531 to a center of the first intermediate resonance pillar 533 is less than 90 degrees. An angle θ2 between a connecting line L3 connecting a center of the input-output resonance pillar 532 to a center of the nearest one of the input-output pillar 522 and a connecting line L4 connecting the center of the input-output resonance pillar 532 to a center of the third intermediate resonance pillar 535 is less than 90 degrees.

The band-pass filter 5 in this embodiment further has features as following.

The band-pass filter 5 further includes a floating conductor 582. The fifth capacitive conductor 565 connected to the input-output resonance pillar 532 and the fourth capacitive conductor 564 connected to the third intermediate resonance pillar 535 are adjacent to each other. The floating conductor 582 is disposed to overlap with and be spaced apart from the fifth capacitive conductor 565 and the fourth capacitive conductor 564. The floating conductor 582 is disposed between the first ends 53a and the second ends 53b of the resonance pillars 53. The floating conductor 581, 582 is disposed closer to the second ends 53b and farther from the first ends 53a. The floating conductor 582 is not electrically connected to any element and is electrically floating. Thereby, the fourth capacitive conductor 564, the floating conductor 582 and the fifth capacitive conductor 565 may form a capacitor.

As shown in FIG. 24 and FIG. 25, the band-pass effect of the band-pass filter 5 is illustrated. The capacitors C1 in FIG. 24 are respectively formed by the first capacitive conductor 561 and the top layer 552, by the second capacitive conductor 562 and the top layer 552, by the third capacitive conductor 563 and the top layer 552, by the fourth capacitive conductor 564 and the top layer 552, and by the fifth capacitive conductor 565 and the top layer 552 (FIG. 23). The capacitor C5 is formed by the fourth capacitive conductor 564, the floating conductor 582 and the fifth capacitive conductor 565 (FIG. 23).

In FIG. 25, line TL is a schematic plot illustrating the insertion loss with respect to frequency, and line RL is a schematic plot illustrating the return loss with respect to frequency. As known from FIG. 25, signals with a frequency below about 24.50 GHz are almost reflected by the band-pass filter 5 and may not penetrate the band-pass filter 5. Signals with a frequency about 24.50-25.50 GHz partially penetrate the band-pass filter 5 and are partially reflected by the band-pass filter 5. Most of signals with a frequency about 25.50-29.00 GHz penetrate the band-pass filter 5, a band-pass bandwidth of the band-pass filter 5 is about 3.50 GHz, and a central frequency falls approximately 27.25 GHz. Signals with a frequency about 29.00-29.50 GHz partially penetrate the band-pass filter 5 and are partially reflected by the band-pass filter 5. Signals with a frequency above about 29.50 GHz are almost reflected by the band-pass filter 5 and may not penetrate the band-pass filter 5. It may be seen that the band-pass bandwidth of the band-pass filter 5 is about 3.00 GHz. In FIG. 5, the bandwidth of the band-pass filter 1 is about 3.00 GHz. Therefore, compared with the band-pass filter 1 in FIG. 5, the bandwidth of the band-pass filter 5 in this embodiment is widened.

It may be seen that in the higher frequency band (29.0-29.50 GHZ) where “the signals partially penetrate the band-pass filter 5 and are partially reflected by the band-pass filter 5”, the bandwidth is about 0.5 GHZ. In FIG. 20, in the higher frequency band (29.50-31.25 GHz) where “the signals partially penetrate the band-pass filter 4 and are partially reflected by the band-pass filter 4”, the bandwidth is about 1.75 GHz. Therefore, compared with the band-pass filter 4 in FIG. 20, a frequency band of the band-pass filter 5 in this embodiment where “the signals partially penetrate the band-pass filter 5 and are partially reflected by the band-pass filter 5”, i.e. “difficult to be distinguished whether the signals penetrate or not”, is narrowed. In addition, the band-pass bandwidth of the band-pass filter 5 drops more sharply at the high-frequency boundary than that of the band-pass filter 4.

As discussed above, in the band-pass filter in one embodiment of the disclosure, the first ends of the resonance pillars are connected to the bottom layer, and the second ends of the resonance pillars are disposed to be spaced apart from the top layer, so that the resonance pillars themselves form inductors (L), and capacitors (C) are formed between the resonance pillars and the top layer. Therefore, an inductor-capacitor (LC) filter may be formed in a limited space. Thereby, the band-pass filter meets the requirement of miniaturization. The capacity of the capacitor may be increased by disposing the capacitive conductors, thereby being able to adjust the band-pass situation of the band-pass filter. The disposing methods of the capacitor in the equivalent circuit may be increased by disposing the floating conductor, thereby being able to adjust the band-pass situation of the band-pass filter, such as the band-pass bandwidth, the frequency band “difficult to be distinguished whether the signals penetrate or not”, etc.

Although the disclosure is disclosed in the foregoing embodiments, it is not intended to limit the disclosure. All variations and modifications made without departing from the spirit and scope of the disclosure fall within the scope of the disclosure. For the scope defined by the disclosure, please refer to the attached claims.

What is claimed is:

1. A band-pass filter, comprising:
a body;
two input-output pillars, located on two opposite sides of the body in a direction;
a plurality of resonance pillars, disposed in the body, wherein each of the plurality of resonance pillars has a first end and a second end, and the plurality of resonance pillars comprises:
two input-output resonance pillars, respectively disposed adjacent to the two input-output pillars and respectively electrically connected to the two input-output pillars; and
at least one intermediate resonance pillar, located between the two input-output resonance pillars in the direction;
a conductive cage, disposed surrounding the plurality of resonance pillars, wherein the conductive cage comprises a bottom layer, a top layer and a plurality of side connectors, the plurality of side connectors are disposed connecting the bottom layer and the top layer, a plurality of first ends of the plurality of resonance pillars are connected to the bottom layer, a plurality of second ends of the plurality of resonance pillars are disposed to be spaced apart from the top layer, and a minimum distance between each of the plurality of resonance pillars and the plurality of side connectors is less than a minimum distance between the plurality of resonance pillars; and
a plurality of capacitive conductors, disposed in the body and respectively connected to the plurality of second ends of the plurality of resonance pillars, wherein the plurality of capacitive conductors are disposed to be spaced apart from the top layer.

2. The band-pass filter according to claim 1, wherein the body is made of ceramic.

3. The band-pass filter according to claim 1, wherein the conductive cage is disposed to be grounded.

4. The band-pass filter according to claim 1, wherein a distance between the two input-output resonance pillars is greater than a distance between other adjacent two of the plurality of resonance pillars.

5. The band-pass filter according to claim 1, wherein the plurality of side connectors are a plurality of the connecting pillars, and two ends of each of the plurality of the connecting pillars are respectively connected to the bottom layer and the top layer.

6. The band-pass filter according to claim 1, wherein a number of the at least one intermediate resonance pillar is plural, and a minimum distance between each of the two input-output resonance pillars and a plurality of intermediate resonance pillars is less than a minimum distance between adjacent two of the plurality of intermediate resonance pillars.

7. The band-pass filter according to claim 1, wherein the two input-output pillars are closer to the bottom layer and farther from the top layer, and a height of each of the two input-output pillars is one quarter to one half of a height of each of the two input-output resonance pillars.

8. The band-pass filter according to claim 1, wherein an angle between a connecting line from each of the two input-output resonance pillars to the nearest one of the two input-output pillars and a connecting line from each of the two input-output resonance pillars to the nearest one of the intermediate resonance pillars is less than 90 degrees.

9. The band-pass filter according to claim 1, wherein a distance between two of the capacitive conductors connected to the two input-output resonance pillars is less than the minimum distance between two of the plurality of resonance pillars.

10. The band-pass filter according to claim 1, further comprising at least one floating conductor disposed to overlap with and be spaced apart from adjacent two of the plurality of capacitive conductors.

11. The band-pass filter according to claim 10, wherein the at least one floating conductor is disposed between the plurality of first ends and the plurality of second ends of the plurality of resonance pillars, and the at least one floating conductor is disposed closer to the plurality of second ends and farther from the plurality of first ends.

12. The band-pass filter according to claim 10, wherein a number of the at least one floating conductor is plural, and each of floating conductors is disposed to overlap with and be spaced apart from two of the capacitive conductors connected to each of the two input-output resonance pillars.

13. The band-pass filter according to claim 1, wherein
a number of the at least one intermediate resonance pillar is plural, the plurality of intermediate resonance pillars comprises a first intermediate resonance pillar, a second intermediate resonance pillar and a third intermediate resonance pillar, and the first intermediate resonance pillar and the third intermediate resonance pillar are respectively adjacent to the two input-output resonance pillars;
the band-pass filter further comprises a plurality of capacitive conductors and a floating conductor;
the plurality of capacitive conductors are disposed in the body and respectively connected to the plurality of second ends of the plurality of resonance pillars, the plurality of capacitive conductors are disposed to be spaced apart from the top layer;
the plurality of capacitive conductors comprise a first capacitive conductor, a second capacitive conductor, a third capacitive conductor, a fourth capacitive conductor and a fifth capacitive conductor, the first capacitive conductor and the fifth capacitive conductor are respectively connected to the two input-output resonance pillars, the second capacitive conductor, the third capacitive conductor and the fourth capacitive conductor are respectively connected to the first intermediate resonance pillar, the second intermediate resonance pillar and the third intermediate resonance pillar; and
the floating conductor is disposed to overlap with and be spaced apart from the fourth capacitive conductor and the fifth capacitive conductor.
